(19) United States
(12) Patent Application Publication
(10) Pub. No.: US 2014/0241062 A1
(43) Pub. Date: Aug. 28, 2014

(54) Modular, Scalable Rigid Flex Memory Module

(71) Applicant: LSI CORPORATION, San Jose, CA (US)

(72) Inventors: Shad T. Jeseritz, Colorado Springs, CO (US); Jason M. Stuhlsatz, Wichita, KS (US); Gregory P. Shogan, Round Rock, TX (US); Patrick J. Haverty, Manteca, CA (US); Brian D. Stark, San Jose, CA (US); Joseph M. Rubinstein, San Jose, CA (US)

(73) Assignee: LSI CORPORATION, San Jose, CA (US)

(21) Appl. No.: 13/833,198

(22) Filed: Mar. 15, 2013

Related U.S. Application Data
(60) Provisional application No. 61/769,850, filed on Feb. 27, 2013.

(51) Int. Cl. G11C 5/04

(52) U.S. Cl. CPC G11C 5/04
USPC 365/185.17

(57) ABSTRACT

A memory card in a computer system includes a plurality of memory elements on a NAND flash board. The NAND flash board is connected to a controller board by a flexible connector. The flexible connector allows the memory elements and NAND flash controller to be physically separated so that waste heat from one does not impact the other. The flexible connector also allows elements to be organized to create an airflow channel. The airflow channel directs air in such a way as to enhance cooling.

### PRIORITY

The present application claims the benefit under 35 U.S.C. §119(e) of U.S. Provisional Application Ser. No. 61/769,850, filed Feb. 27, 2013, which is incorporated herein by reference.

### BACKGROUND OF THE INVENTION

Flash memory cards are becoming more densely packed. As memory capacity increases and physical size remains relatively constant, heat dissipation becomes a significant issue. Furthermore, waste heat from one component impacts the performance of other components; for example, waste heat from flash memory elements has an adverse impact on flash memory controllers.

Consequently, it would be advantageous if an apparatus existed that is suitable for use in a flash memory card to organize and distribute components within the existing footprint while providing superior heat dissipation.

### SUMMARY OF THE INVENTION

Accordingly, the present invention is directed to a novel apparatus for use in a memory card to organize and distribute components within the existing footprint while providing superior heat dissipation.

In one embodiment of the present invention, a memory card includes a board with memory elements connected by a flexible connector to a board with a NAND flash controller. The flexible connector allows the memory elements to be separated from the NAND flash controller.

In another embodiment of the present invention, memory elements are organized on a NAND flash board and the NAND flash board is connected to a controller board to create an airflow channel for enhanced cooling.

It is to be understood that both the foregoing general description and the following detailed description are exemplary and explanatory only and are not restrictive of the invention claimed. The accompanying drawings, which are incorporated in and constitute a part of the specification, illustrate an embodiment of the invention and together with the general description, serve to explain the principles.

### BRIEF DESCRIPTION OF THE DRAWINGS

The numerous advantages of the present invention may be better understood by those skilled in the art by reference to the accompanying figures in which:

FIG. 1A shows a perspective view of a block diagram of a memory card with a flexible connector folded into a compact configuration;

FIG. 1B shows a perspective view of a block diagram of a memory card with a flexible connector folded into a compact configuration;

FIG. 2 shows a block diagram of a memory card with a flexible connector open into a flat configuration; and

FIG. 3 shows a top view of a block diagram of three NAND flash board circuits with flexible connectors.

### DETAILED DESCRIPTION OF THE INVENTION

Reference will now be made in detail to the subject matter disclosed, which is illustrated in the accompanying drawings. The scope of the invention is limited only by the claims; numerous alternatives, modifications and equivalents are encompassed. For the purpose of clarity, technical material that is known in the technical fields related to the embodiments has not been described in detail to avoid unnecessarily obscuring the description.

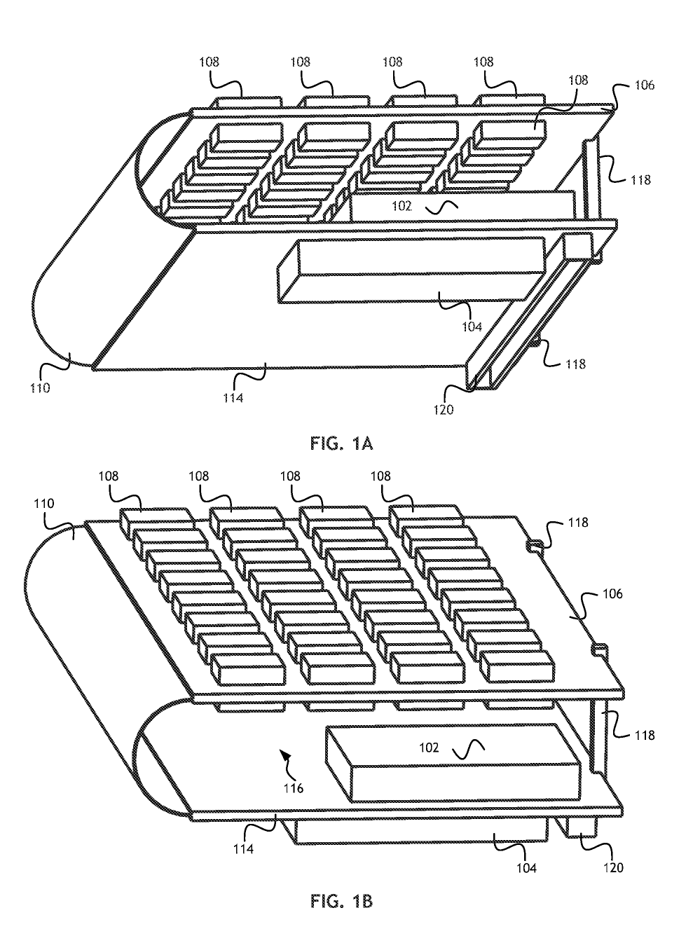

Referring to FIGS. 1A and 1B, perspective view of a block diagram of a memory card with a flexible connector folded into a compact configuration are shown. In at least one embodiment of the present invention, a NAND flash board 106 includes one or more memory elements 108. In at least one embodiment, the memory elements 108 are NAND based memory elements 108 comprising one or more D flip-flop circuits. The NAND flash board 106 is connected to a controller board 114 through a flexible connector 110 configured to allow communication with and provide power to the memory elements 108. In at least one embodiment, the flexible connector 110 is a thin plastic element including circuitry to connect the memory elements 108 on the NAND flash board 106 to a NAND flash controller 104 on the controller board 114. In another embodiment, the flexible connector 110 is a semi-rigid element capable of supporting the NAND flash board 106 a desired distance away from the controller board 114. In at least one embodiment, the controller board 114 also includes random access memory 102. The controller board 114 includes elements such as a host bus adapter connector 120 configured for a host bus adapter to allow a computer system access to the memory elements 108.

In at least one embodiment of the present invention, the NAND flash board 106 and controller board 114 define an airflow channel 116. In one embodiment, the airflow channel 116 directs airflow produced by a separate airflow device such as a fan. In another embodiment, heat from the memory elements 108 produces air circulation, and such air circulation is directed by the airflow channel 116. The airflow channel 116 enhances cooling by increasing air circulation locally with regards to the memory elements 108 and the NAND flash controller 104. In at least one embodiment, the NAND flash controller 104 on a portion of the controller board 114 opposite the portion defining the airflow channel 116 to further enhance cooling.

In at least one embodiment of the present invention, a memory card having a flexible connector 110 includes one or more support elements 118 to maintain physical separation between a NAND flash board 106 and a controller board 114 or host bus adapter 100. The support element 118 should not obstruct the airflow channel 116 more than necessary to maintain a desired separation. In at least one embodiment, support elements 118 include plastic engaging the entire peripheral surface or edge of the controller board 114 and the NAND flash board 106.

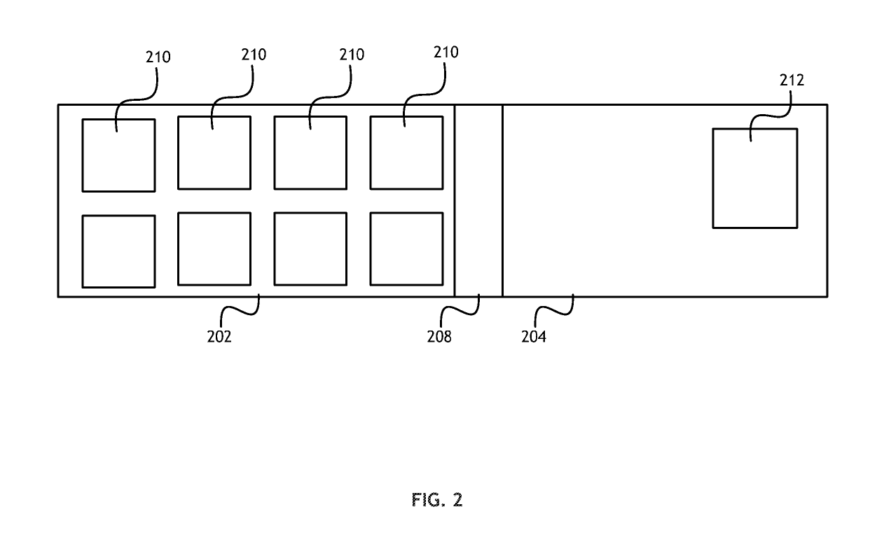

Referring to FIG. 2, a block diagram of a memory card with a flexible connector open into a flat configuration is shown. In at least one embodiment of the present invention, a NAND flash board 202 includes one or more memory elements 210 such as NAND based flash memory. The NAND flash board 202 is connected to a controller board 204. In at least one embodiment, the NAND flash board 202 is connected to the controller board 204 through a flexible connector 208. In at least one embodiment, the flexible connector 208 as a thin plastic element including circuitry to connect the memory elements 210 on the NAND flash board 202 to a NAND flash controller 212 on the controller board 204. The controller board 204 is configured to connect to a host bus adapter to allow a computer system access to the memory elements 210.

Where the controller board 204 and NAND flash board 202 are connected by a flexible connector 208, the controller board 204 and NAND flash board 202 are positionable for enhanced heat dissipation. Furthermore, physical separation of memory elements 210 from the NAND flash controller 212 enhances performance by diminishing the effects of waste heat from one component to another.

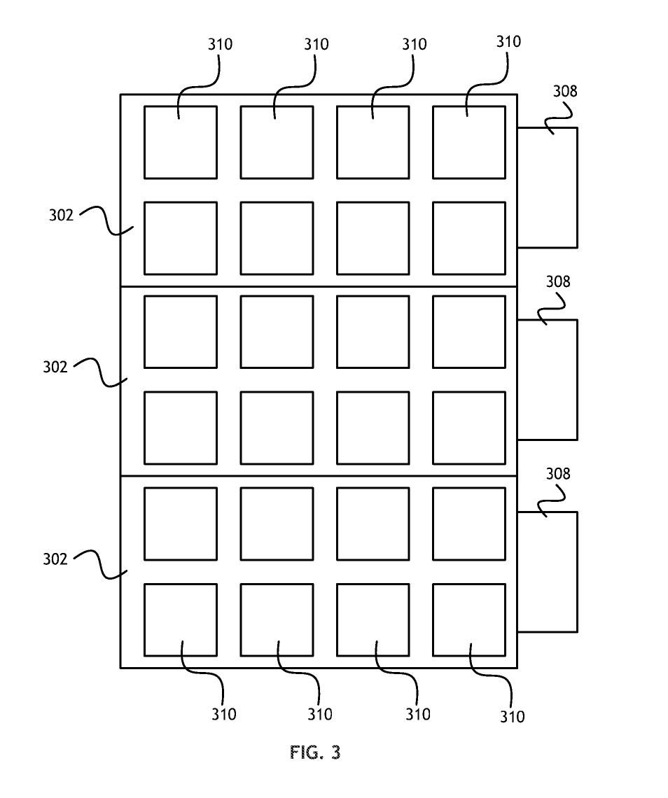

Referring to FIG. 3, a top view of a block diagram of three NAND flash board circuits with flexible connectors is shown. In at least one embodiment of the present invention, a memory card includes two or more NAND flash boards 302. Each NAND flash board 302 includes a plurality of memory elements 310 such as NAND based flash memory. Each NAND flash board 302 is connected to a NAND flash controller (not shown) through a flexible connector 308.

In at least one embodiment, NAND flash boards 302 are physically separate from each other. In another embodiment, the NAND flash boards 302 are logically separated such that all of the NAND flash boards 302 comprise a single physical element without any common circuitry. Where the NAND flash boards 302 are physically separated, each NAND flash board 302 can be positioned or oriented to change the shape of an airflow channel defined by the NAND flash boards 302 and a controller board. Alternatively, each NAND flash board 302 can be positioned or oriented to further enhance heat dissipation.

It is believed that the present invention and many of its attendant advantages will be understood by the foregoing description of embodiments of the present invention, and it will be apparent that various changes may be made in the form, construction, and arrangement of the components thereof without departing from the scope and spirit of the invention or without sacrificing all of its material advantages. The form herein before described being merely an explanatory embodiment thereof, it is the intention of the following claims to encompass and include such changes.

What is claimed is:

1. A computer system comprising:
a memory card comprising:
a controller board including a NAND flash controller;
a first NAND flash board including a plurality of memory elements; and
a first flexible connector connecting the first NAND flash board to the controller board,
wherein the first flexible connector is configured to:
maintain data communication between the NAND flash controller and the plurality of memory elements on the first NAND flash board; and
physically separate the controller board from the first NAND flash board.

2. The system of claim 1, wherein at least one of the plurality of memory elements is a flash memory element.

3. The system of claim 1, wherein the first flexible connector is configured to orient the first NAND flash board in relation to the controller board such that the first NAND flash board and controller board define an airflow channel.

4. The system of claim 3, further comprising a support element configured to maintain the orientation of the first NAND flash board in relation to the controller board.

5. The system of claim 1, further comprising:
a second NAND flash board including a plurality of memory elements; and
a second flexible connector connecting the second NAND flash board to the controller board,
wherein the second flexible connector is configured to:
maintain data communication between the NAND flash controller and the plurality of memory elements on the second NAND flash board; and
physically separate the controller board from the second NAND flash board.

6. The system of claim 5, wherein:
the first flexible connector is configured to orient the first NAND flash board in relation to the controller board and the second NAND flash board such that the first NAND flash board, the second NAND flash board and controller board define an airflow channel; and
the second flexible connector is configured to orient the second NAND flash board in relation to the controller board and the first NAND flash board such that the first NAND flash board, the second NAND flash board and controller board define an airflow channel.

7. The system of claim 1, further comprising:
a second NAND flash board including a plurality of memory elements; and
a second flexible connector connecting the second NAND flash board to the first NAND flash board,
wherein the second flexible connector is configured to:
maintain data communication between the NAND flash controller and the plurality of memory elements on the second NAND flash board; and
physically separate the controller board from the second NAND flash board and the first NAND flash board.

8. The system of claim 7, wherein the first flexible connector is configured to orient the first NAND flash board in relation to the controller board, and the second flexible connector is configured to orient the second NAND flash board in relation to the first NAND flash board, such that the first NAND flash board, the second NAND flash board and controller board define an airflow channel.

9. A memory card comprising:
a controller board including a NAND flash controller;
a first NAND flash board including a plurality of memory elements; and
a first flexible connector connecting the first NAND flash board to the controller board,
wherein the first flexible connector is configured to:
maintain data communication between the NAND flash controller and the plurality of memory elements on the first NAND flash board; and
physically separate the controller board from the first NAND flash board.

10. The memory card of claim 9, wherein at least one of the plurality of memory elements is a flash memory element.

11. The memory card of claim 9, wherein the first flexible connector is configured to orient the first NAND flash board in relation to the controller board such that the first NAND flash board and controller board define an airflow channel.

12. The memory card of claim 11, further comprising a support element configured to maintain the orientation of the first NAND flash board in relation to the controller board.

13. The memory card of claim 9, further comprising:
a second NAND flash board including a plurality of memory elements; and
a second flexible connector connecting the second NAND flash board to the controller board,
wherein the second flexible connector is configured to:
maintain data communication between the NAND flash controller and the plurality of memory elements on the second NAND flash board; and
physically separate the controller board from the second NAND flash board.

14. The memory card of claim 13, wherein:
the first flexible connector is configured to orient the first NAND flash board in relation to the controller board and the second NAND flash board such that the first NAND flash board, the second NAND flash board and controller board define an airflow channel; and
the second flexible connector is configured to orient the second NAND flash board in relation to the controller board and the first NAND flash board such that the first NAND flash board, the second NAND flash board and controller board define an airflow channel.

15. The memory card of claim 9, further comprising:
a second NAND flash board including a plurality of memory elements; and
a second flexible connector connecting the second NAND flash board to the first NAND flash board,
wherein the second flexible connector is configured to:
maintain data communication between the NAND flash controller and the plurality of memory elements on the second NAND flash board; and
physically separate the controller board from the second NAND flash board and the first NAND flash board.

16. The memory card of claim 15, wherein the first flexible connector is configured to orient the first NAND flash board in relation to the controller board, and the second flexible connector is configured to orient the second NAND flash board in relation to the first NAND flash board, such that the first NAND flash board, the second NAND flash board and controller board define an airflow channel.

17. A flash memory card comprising:
a controller board including a NAND flash controller;
a first NAND flash board including a plurality of flash memory elements;
a first flexible connector connecting the first NAND flash board to the controller board;
a second NAND flash board including a plurality of flash memory elements; and
a second flexible connector connecting the second NAND flash board to the controller board,
wherein:
the first flexible connector is configured to:
maintain data communication between the NAND flash controller and the plurality of flash memory elements on the first NAND flash board; and
physically separate the controller board from the first NAND flash board; and
the second flexible connector is configured to:
maintain data communication between the NAND flash controller and the plurality of flash memory elements on the second NAND flash board; and
physically separate the controller board from the second NAND flash board.

18. The flash memory card of claim 17, wherein the first flexible connector is configured to orient the first NAND flash board in relation to the controller board such that the first NAND flash board, the second NAND flash board and controller board define an airflow channel.

19. The flash memory card of claim 18, wherein the first NAND flash board and the second NAND flash board are physically separate.

20. The flash memory card of claim 19, wherein the second flexible connector is configured to orient the second NAND flash board in relation to the controller board and the first NAND flash board such that the first NAND flash board, the second NAND flash board and controller board define an airflow channel.
